(19) United States
(12) Patent Application Publication
(10) Pub. No.: US 2020/0378833 A1
(43) Pub. Date: Dec. 3, 2020

(54) INFRARED DETECTION APPARATUS

(71) Applicants: SHARP KABUSHIKI KAISHA, Osaka (JP); THE UNIVERSITY OF TOKYO, Tokyo (JP)

(72) Inventors: HIROFUMI YOSHIKAWA, Osaka (JP); TAKAHIRO DOE, Osaka (JP); YASUHIKO ARAKAWA, Tokyo (JP)

(21) Appl. No.: 16/889,095

(22) Filed: Jun. 1, 2020

(30) Foreign Application Priority Data
Jun. 3, 2019 (JP) 2019-103758

(51) Int. Cl. G01J 5/28; G01J 5/00; H01L 31/0352; H01L 31/109

(52) U.S. Cl. CPC G01J 5/28; H01L 31/109; H01L 31/035218; G01J 5/0003

(57) ABSTRACT

Provided is an infrared detection apparatus without a bandpass filter and capable of reducing an error produced when a temperature of an object is calculated. A detection unit has a quantum-dot stacked structure. A first voltage and a second voltage are respectively provided for setting a first responsivity peak wavelength and a second responsivity peak wavelength to be used for detecting an infrared ray in the detection unit. The second responsivity peak wavelength is different from the first responsivity peak wavelength. A detector detects (i) a first photocurrent to be output from the detection unit when the first voltage is applied to the photoelectric conversion layer, and (ii) a second photocurrent to be output from the detection unit when the second voltage is applied to the photoelectric conversion layer. A calculator calculates a temperature of an object based on the first photocurrent and the second photocurrent detected by the detector.

The present application claims priority to Japanese Patent Application No. 2019-103758, filed Jun. 3, 2019, the contents of which are incorporated herein by reference in its entirety.

### BACKGROUND OF THE INVENTION

### Field of the Invention

The present invention relates to an infrared detection apparatus.

### Description of the Background Art

A typical infrared sensor known in the art is capable of adjusting emissivity. Moreover, a near-infrared temperature measuring apparatus includes: a near-infrared sensor; and two kinds of bandpass filters, and eliminates the need of emissivity correction.

Moreover, J. C. Campbell, and A. Madhukar, “Quantum-Dot Infrared Photodetectors,” Proceedings of the IEEE 95, 1815 (2007) (hereinafter referred to as Non-Patent Literature 1) discloses a quantum-dot structure having an InAs/InGaAs/GaAs structure. Here, InAs is of quantum dots, InGaAs is of a quantum well layer, and GaAs is of a barrier layer.

Non-Patent Literature 1 further discloses that a bias is applied to the quantum-dot structure to obtain different responsivity peak wavelengths. In particular, use of a positive bias and a negative bias achieves a shift of a peak between peaks of approximately 8.4 μm and 9 μm.

Furthermore, A. V. Barve, S. J. Lee, S. K. Noh, and S. Krishna, “Review of current progress in quantum dot infrared photodetectors”, Laser & Photonics Reviews_4,_738_(2010) (hereinafter referred to as Non-Patent Literature 2) discloses a quantum-dot structure in which quantum dots are sandwiched between a quantum well layer and a barrier layer. Here, the quantum well layer includes: a first quantum well layer acting as an underlayer for the quantum dots; and a second quantum well layer acting as a cap layer for the quantum dots.

This quantum-dot structure involves transition of carriers from a confined level of the quantum dots to (i) a level of the quantum well layer, and to (ii) a continuous level of the barrier layer. When a low bias is applied to the quantum-dot structure, mainly obtained is a photocurrent generated by carriers transferred from the confined level of the quantum dots to the continuous level of the barrier layer. When a high bias is applied to the quantum-dot structure, mainly obtained is a photocurrent generated by carriers transferred from the confined level of the quantum dots to the level of the quantum well layer.

However, a conventional infrared sensor requires an emissivity to be input, causing a large temperature measurement error depending on an object. A near-infrared temperature measuring apparatus, utilizing a two-color temperature measurement method which does not require correction of emissivity, can reduce temperature measurement errors depending on an object; however, the apparatus requires two kinds of bandpass filters. Moreover, Non-Patent Literatures 1 and 2 fail to disclose and suggest measurement of a temperature of an object by the two-color temperature measurement method using two responsivity peaks.

An embodiment of the present invention provides an infrared detection apparatus without a bandpass filter and capable of reducing an error produced when a temperature of an object is calculated.

### SUMMARY

### First Aspect

According to an embodiment of the present invention, an infrared detection apparatus includes: a detection unit; an operation device; a detector; and a calculator. The detection unit including a photoelectric conversion layer constituted by a quantum-dot stacked structure including: quantum dots; a first quantum well layer surrounding the quantum dots; a first barrier layer sandwiching the quantum dots and the first quantum well layer. The operation device applies a first voltage and a second voltage to the photoelectric conversion layer, the first voltage and the second voltage being respectively provided for setting a first responsivity peak wavelength and a second responsivity peak wavelength to be used for detecting an infrared ray with the photoelectric conversion layer, and the second responsivity peak wavelength being different from the first responsivity peak wavelength. The detector detects (i) a first photocurrent to be output from the detection unit when the first voltage is applied to the photoelectric conversion layer, and (ii) a second photocurrent to be output from the detection unit when the second voltage is applied to the photoelectric conversion layer. The calculator calculates a temperature of an object based on the first photocurrent and the second photocurrent detected by the detector.

### Second Aspect

In the second aspect, the photoelectric conversion layer includes a plurality of the quantum-dot stacked structures stacked together.

### Third Aspect

In the first or second aspect, the calculator calculates a temperature of the object based on the first photocurrent and the second photocurrent, using a two-color temperature measurement method.

### Fourth Aspect

In any one of the first to third aspects, the detection unit detects the infrared ray emitted from the object of which an emissivity in the first responsivity peak wavelength and an emissivity in the second responsivity peak wavelength are equal.

### Fifth Aspect

In any one of the first to fourth aspects, the first responsivity peak wavelength and the second responsivity peak wavelength appear due to the same transition of carriers in the photoelectric conversion layer.

### Sixth Aspect

In any one of the first to fifth aspects, the first responsivity peak wavelength and the second responsivity peak wavelength are set in a wavelength range of the same atmospheric window.

### Seventh Aspect

In the sixth aspect, a responsivity peak wavelength other than the first responsivity peak wavelength and the second responsivity peak wavelength is set in a wavelength range other than the wavelength range of the same atmospheric window.

### Eight Aspect

In any one of the first to third aspects, the first responsivity peak wavelength appears in a first transition of carriers in the photoelectric conversion layer, and the second responsivity peak wavelength appears in a second transition of the carriers in the photoelectric conversion layer, the second transition being different from the first transition.

### Ninth Aspect

In the eight aspect, when the first voltage is applied to the photoelectric conversion layer, a first responsivity divided by a second responsivity equals 2 or greater, the first responsivity being a responsivity of the first responsivity peak wavelength and the second responsivity being a responsivity of the second responsivity peak wavelength, and when second voltage is applied to the photoelectric conversion layer, a third responsivity divided by a fourth responsivity equals 2 or greater, the third responsivity being a responsivity of the second responsivity peak wavelength and the fourth responsivity being a responsivity of the first responsivity peak wavelength.

### Tenth Aspect

In the eight aspect, the first responsivity peak wavelength is set within an area of a first atmospheric window having a first wavelength range, and the second responsivity peak wavelength is set within in an area of a second atmospheric window having a second wavelength range longer than the first wavelength range.

### Eleventh Aspect

In the tenth aspect, the quantum dots are made of InAs, the first quantum well layer is made of InGaAs, and the first barrier layer is made of AlGaAs.

### Twelfth Aspect

In the tenth aspect, the photoelectric conversion layer further includes a second quantum well layer between the first quantum well layer and the first barrier layer.

### Thirteenth Aspect

In the twelfth aspect, the quantum dots are made of InAs, the first quantum well layer is made of InGaAs, and the first barrier layer is made of AlGaAs.

### Fourteenth Aspect

In any one of the eighth to tenth aspects, the detection unit further includes: a contact layer, and a second barrier layer. The second barrier layer is placed between the photoelectric conversion layer and the contact layer, and is larger in band gap than the first barrier layer.

### Fifteenth Aspect

In the fourteenth aspect, the quantum dots are made of InAs, the first quantum well layer is made of InGaAs, and the first barrier layer is made of AlGaAs having a first band gap. The second barrier layer is made of AlGaAs having a second band gap larger than the first band gap.

### Sixteenth Aspect

In the eight to fifteenth aspects, the first voltage and the second voltage is either positive or negative.

The present invention can reduce an error produced when a temperature of an object is calculated.

### BRIEF DESCRIPTION OF THE DRAWINGS

FIG. 1 schematically illustrates an infrared detection apparatus according a first embodiment of the present invention;

FIG. 2 schematically illustrates a detection unit illustrated in FIG. 1;

FIG. 3 illustrates a first step showing how to manufacture the detection unit illustrated in FIG. 2;

FIG. 4 illustrates a second step showing how to manufacture the detection unit illustrated in FIG. 2;

FIG. 5 illustrates a third step showing how to manufacture the detection unit illustrated in FIG. 2;

FIG. 6 illustrates an energy band in a quantum-dot stacked structure of the detection unit illustrated in FIG. 2;

FIG. 7 illustrates a relationship between a transmittance and a wavelength in the first embodiment;

FIG. 8 illustrates another relationship between the transmittance and the wavelength in the first embodiment;

FIG. 9 shows a flowchart to explain how to calculate a temperature of an object according to the first embodiment;

FIG. 10 schematically illustrates an infrared detection apparatus according a second embodiment;

FIG. 11 schematically illustrates a detection unit illustrated in FIG. 10;

FIG. 12 illustrates energy bands in a quantum-dot stacked structure of the detection unit illustrated in FIG. 11;

FIG. 13 illustrates a relationship between a transmittance and a wavelength in the second embodiment;

FIG. 14 illustrates another relationship between the transmittance and the wavelength in the second embodiment;

FIG. 15 shows a flowchart to explain how to calculate a temperature of an object according to the second embodiment;

FIG. 16 schematically illustrates another detection unit according the second embodiment;

FIG. 17 schematically illustrates an infrared detection apparatus according a third embodiment;

FIG. 18 schematically illustrates a detection unit illustrated in FIG. 17; and

FIG. 19 illustrates an energy band in a photoelectric conversion layer, a single-side barrier layer, and a contact layer included in the detection unit illustrated in FIG. 18.

### DESCRIPTION OF THE PREFERRED EMBODIMENTS

Embodiments of the present invention are described in detail below, with reference to the drawings. Note that identical reference signs are used to denote identical or substantially identical components, and the descriptions of the components shall not be repeated.

### First Embodiment

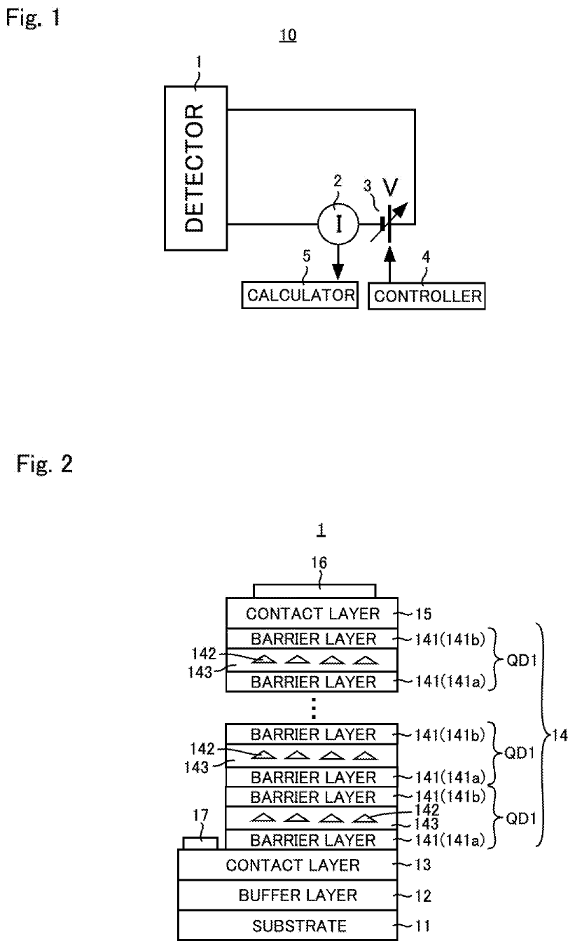

FIG. 1 schematically illustrates an infrared detection apparatus according a first embodiment of the present invention. With reference to FIG. 1, an infrared detection apparatus 10 according to the first embodiment of the present invention includes: a detection unit 1; a detector 2; an operation device 3; a controller 4; and a calculator 5.

The detection unit 1 is a quantum-dot infrared photo detector (QDIP). The QDIP may be either a single element or an imager. While a voltage from the operation device 3 is applied to the detection unit 1, the detection unit 1 detects an infrared ray from an object using two responsivity peak wavelengths. The detection unit 1 then outputs a current in accordance with a radiation intensity of the detected infrared ray.

The detector 2 measures the current output from the detection unit 1, and outputs the measured current to the calculator 5. The detection unit 2 is an ammeter.

In response to the control from the controller 4, the operation device 3 applies voltages V1 and V2 to the detection unit 1, so that two respective responsivity peak wavelengths are set for the detection unit 1. The detection unit 3 is a variable voltmeter.

The controller 4 causes the operation device 3 to apply the voltages V1 and V2 to the detection unit 1, so that the detection unit 1 has two responsivity peak wavelengths.

The calculator 5 receives from the detector 2: a current I1 output from the detection unit 1 when the voltage V1 is applied to the detection unit 1; and a current I2 output from the detection unit 1 when the voltage V2 is applied to the detection unit 1. Based on the received currents I1 and I2, the calculator 5 calculates a temperature of the object with a technique to be described later.

FIG. 2 schematically illustrates the detection unit 1 illustrated in FIG. 1. With reference to FIG. 2, the detection unit 1 includes: a substrate 11; a buffer layer 12; contact layers 13 and 15, a photoelectric conversion layer 14; and electrodes 16 and 17.

The buffer layer 12 is placed on and above the substrate 11. The contact layer 13 is placed on and above the buffer layer 12. The photoelectric conversion layer 14 is placed on and above the contact layer 13. The photoelectric conversion layer 14 includes: a barrier layer 141; quantum dots 142; and a quantum well layer 143.

The quantum well layer 143 surrounds the quantum dots 142. The barrier layer 141 includes barrier layers 141a and 141b. The barrier layers 141a and 141b sandwich the quantum well layer 143 in a thickness direction. The quantum dots 142, the quantum well layer 143, and the two barrier layers 141; namely the barrier layers 141a and 141b, constitute a quantum-dot stacked structure QD1. Hence, the photoelectric conversion layer 14 includes multiple quantum-dot stacked structures QD1 stacked together. In this embodiment of the present invention, for example, 10 quantum-dot stacked structures QD1 are stacked together. The multiple quantum-dot stacked structures QD1 stacked together can improve responsivity, contributing to obtaining a large photocurrent.

The lowermost quantum-dot stacked structure QD1 includes: the barrier layer 141a (one of the two barrier layers 141) placed on and above the contact layer 13; the quantum well layer 143 surrounding the quantum dots 142 and placed on and above the barrier layer 141a: and the barrier layer 141b (the other one of the two barrier layers 141) placed on and above the quantum well layer 143. On the lowermost quantum-dot stacked structure QD1, the components are stacked together in the order of the barrier layer 141, the quantum well layer 143, the quantum dots 142, the quantum well layer 143, and the barrier layer 141, so that the quantum well layers 143 surrounding the quantum dots 142 are each separated by the barrier layers 141. Hence, multiple quantum-dot stacked structures QD1 are stacked together.

The contact layer 15 is placed on and above the photoelectric conversion layer 14. The electrode 16 is placed on and above the contact layer 15. The electrode 17 is placed on and above the contact layer 13.

The substrate 11 is made of, for example, GaAs. The buffer layer 12 is made of, for example, GaAs. The contact layer 13 is made of, for example, n-type GaAs. For example, the barrier layer 141 is made of GaAs, and has a thickness of 40 nm with the barrier layers 141a and 141b combined. Each of the barrier layers 141a and 141b has a thickness of, for example, 20 nm.

For example, each of the quantum dots 142 is made of InAs, and shaped into a pyramid. The quantum dot 142 has, for example, a height of 5 nm and a length of the base of 25 nm. For example, the quantum well layer 143 is made of InGaAs, and has a thickness of 10 nm. An exemplary composition of InGaAs is In_{0.15}Ga_{0.85}As. An exemplary distance between the lower face of the quantum well layer 143 and the base of the quantum dot 142 is 5 nm.

The contact layer 15 is, for example, made of n-type GaAs. The electrodes 16 and 17 are made of, for example, AuGeNi/Au.

Note that other semiconductors such as InGaP, InAlAs, AlGaAsSb, AlGaInP, and InAlGaAs are appropriately combined to form the quantum-dot stacked structures QD1 and the detection unit 1.

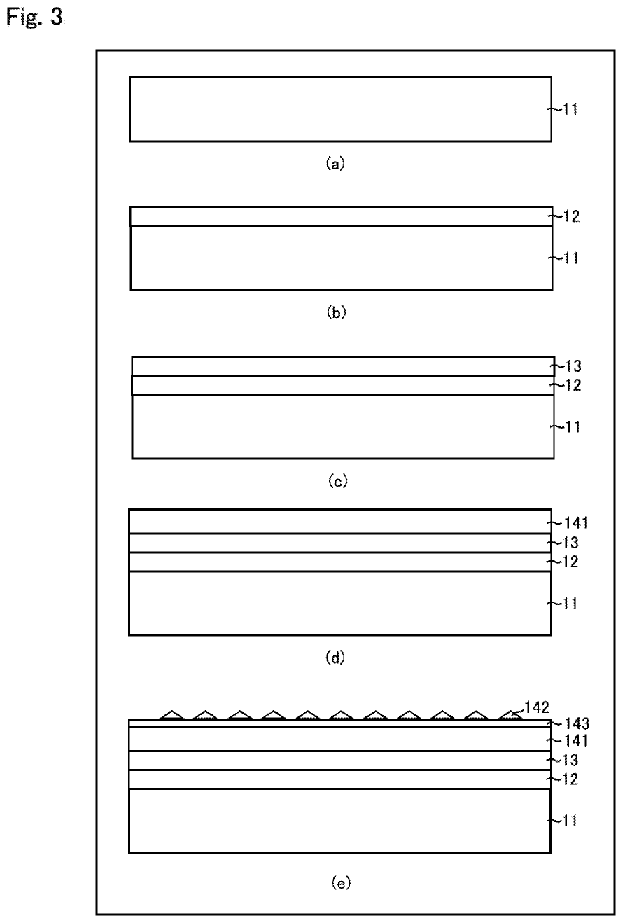

FIGS. 3 to 5 illustrate first to third steps showing how to manufacture the detection unit 1 in FIG. 2. Note that the illustrations for steps (a) to (j) in FIGS. 3 to 5 constitute a single step.

With reference to FIG. 3, when the manufacture of the detection unit 1 starts, the substrate 11 made of semi-conductive GaAs is supported inside a molecular beam epitaxy (MBE) apparatus (the step (a) in FIG. 3).

Then, the buffer layer 12 is formed on the substrate 11 with the MBE (the step (b) in FIG. 3). Here, an example of the buffer layer 12 is a GaAs layer having a thickness of 200 nm. The formed buffer layer 12 can improve crystallinity of the photoelectric conversion layer 14 to be formed on the butter layer 12. The improvement in crystallinity makes it possible to provide the infrared detector with the photoelectric conversion layer 14 having sufficient photoreception efficiency.

After the step (b), the contact layer 13 is formed on the buffer layer 12 with the MBE (the step (c) in FIG. 3). Here, an example of the contact layer 13 is an n-type GaAs layer having a thickness of 500 nm.

Then, the barrier layer 141 (the barrier layer 141a) made of GaAs is formed on the contact layer 13 with the MBE (the step (d) in FIG. 3).

Then, InGaAs having a thickness of 5 nm is formed as the quantum well layer 143 with the MBE. Formed on the quantum well layer 143 are quantum dots 142 made of InAs (the step (e) in FIG. 3).

Here, the quantum dots 142 are formed with a technique called the Stranski-Krastanov (S-K) growth.

More specifically, InGaAs crystal-grows as the quantum well layer 143. With a self-organizing mechanism, the quantum dots 142 made of InAs are formed.

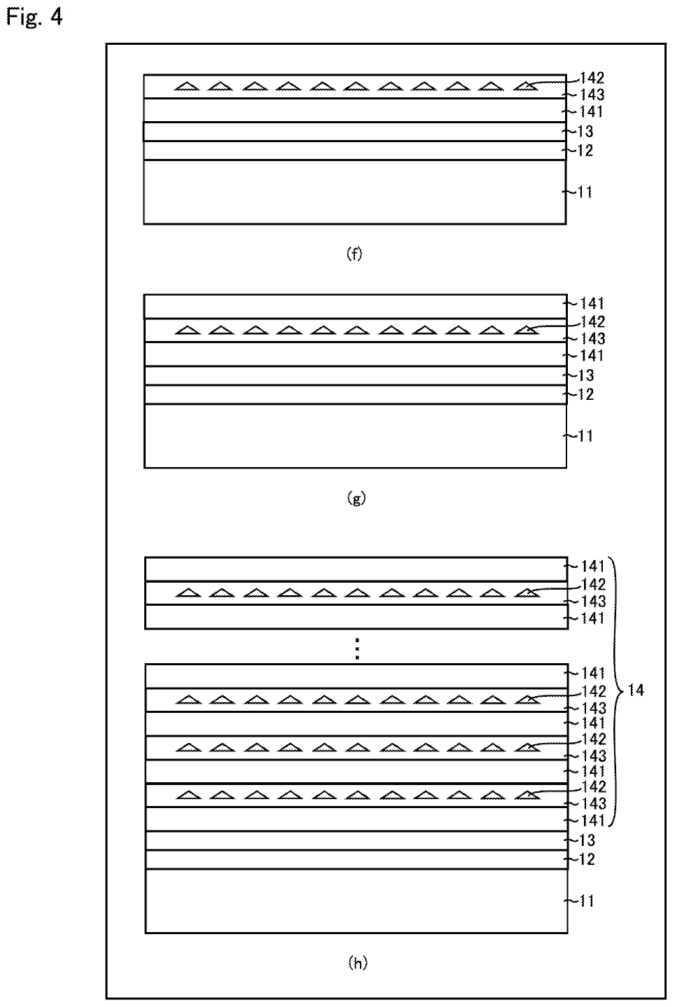

Then, InGaAs is formed with the MBE as the quantum well layer 143, so that the formed quantum well layer 143 having a thickness of 10 nm surrounds the quantum dots 142 (the step (f) in FIG. 4).

Then, the barrier layer 141 (the barrier layer 141b) made of GaAs is formed on the quantum well layer 143 by the MBE (the step (g) in FIG. 4).

After that, the quantum well layer 143, the quantum dots 142, the quantum well layer 143, and the barrier layer 141 are repeatedly formed with the MBE to form the photoelectric conversion layer 14 (the step (h) in FIG. 4.).

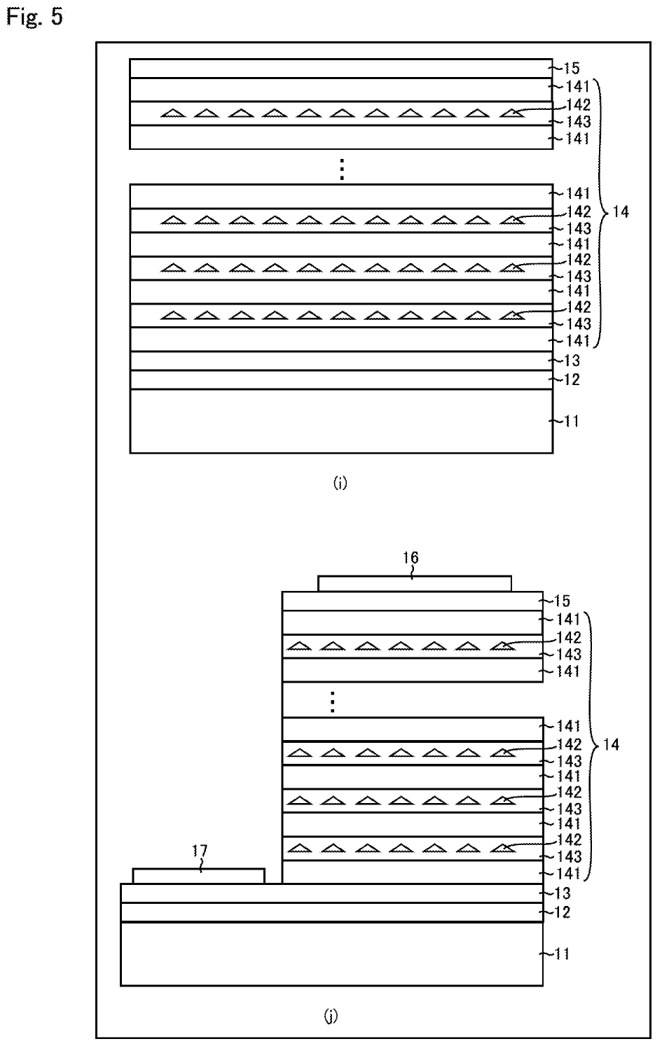

Then, formed as the contact layer 15 with the MBE is an n-type GaAs layer having a thickness of 200 nm (the step (i) in FIG. 5).

The stacked product is taken out of the MBE apparatus. With a photolithography technique and wet etching, the photoelectric conversion layer 14 and the contact layer 15 are partially removed so that the electrode 16 and the electrode 17 are respectively formed on the contact layer 15 and the contact layer 13. Hence, the detection unit 1 is completed (the step (j) in FIG. 5).

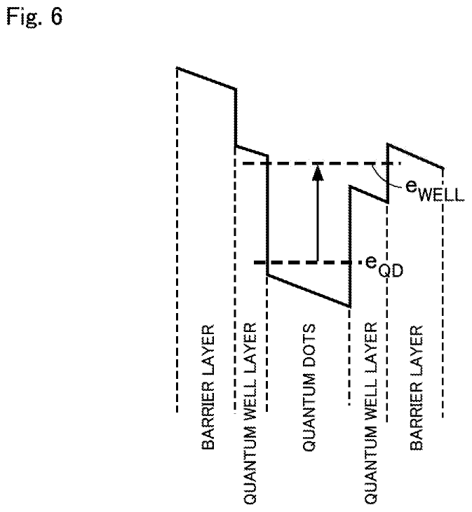

FIG. 6 illustrates an energy band in the quantum-dot stacked structure QD1 of the detection unit 1 illustrated in FIG. 2. Note that FIG. 6 illustrates an energy band in the quantum-dot stacked structure QD1 when a voltage is applied.

With reference to FIG. 6, a confined level e_{QD} is found in the quantum dots 142 and a level e_{WELL} is found in the quantum well layer 143. Then, a voltage is applied to the photoelectric conversion layer 14, and carriers transit from the confined level e_{QD} of the quantum dots 142 to the level e_{WELL} of the quantum well layer 143, thereby detecting an infrared ray. Different voltages are applied to the photoelectric conversion layer 14, so that, in the transition of the carriers from the confined level e_{QD} of the quantum dots 142 to the level e_{WELL} of the quantum well layer 143, two different responsivity peak wavelengths appear in a wavelength range of the atmospheric window, thereby detecting an infrared ray. The two different responsivity peak wavelengths are made with the quantum confirmed Stark effect.

Note that the atmospheric window is a wavelength range having a high transmittance in the atmosphere. Two wavelength ranges are commonly known; namely, a range from 3 to 5.5 μm and a range from 8 to 14 μm. In the present application, when the former is referred to as a first wavelength range and the latter is referred to as a second wavelength range, for example, both of the wavelengths are referred to as the atmospheric window. Moreover, in the case where multiple wavelengths are included in either one of the wavelength areas, the case is to be referred to as “within the wavelength range of the same atmospheric window” or “within the area of the same atmospheric window.”

Furthermore, detected may be an absorption caused by the transition of the carriers from the confined level e_{QD} of the quantum dots 142 to a continuous level e_{CB} in a conduction band of the barrier layer 141. Such an absorption is handled as described below.

(1) The absorption in the transition of the carriers from the confined level e_{QD} of the quantum dots 142 to the continuous level e_{CB} in the conduction band of the barrier layer 141 is corrected to be eliminated.

(2) In order to cause, out of the area of the atmospheric window, the absorption in the transition of the carriers from the confined level e_{QD} of the quantum dots 142 to the continuous level e_{CB} of the barrier layer 141, each of the parameters of the quantum-dot stacked structure QD1 (for example, a size of the quantum dot 142) is adjusted.

(3) The voltage to be applied to the photoelectric conversion layer 14 is adjusted, so that a photocurrent generated by the transition of the carriers from the continuous level e_{QD} of the quantum dots 142 to the level e_{WELL} of the quantum well layer 143 is mainly detected.

In the above item (2), the absorption in the transition of the carriers from the confined level e_{QD} of the quantum dots 142 to the level e_{WELL} of the quantum well layer 143 is set to the area of the atmospheric window, and the absorption in the transition of the carriers from the confined level e_{QD} of the quantum dots 142 to the continuous level e_{CB} of the barrier layer 141 is set to an area other than that of the atmospheric window. Such settings prevent detection of the absorption in the transition of the carriers from the confined level e_{QD} to the continuous level e_{CB}.

Moreover, in the item (3), a voltage higher than that to be applied to the photoelectric conversion layer 14 is applied to the photoelectric conversion layer 14 in order to detect the absorption in the transition of the carriers from the confined level e_{QD} of the quantum dots 142 to the continuous level e_{CB} of the barrier layer 141. Hence, the photocurrent generated by the transition of the carriers from the confined level e_{QD} of the quantum dots 142 to the level e_{WELL} of the quantum well layer 143 is mainly detected.

Note that the transition of the carriers from the confined level e_{QD} of the quantum dots 142 to the continuous level e_{CB} of the barrier layer 141 is the transition of the carriers from the confined level eon of the quantum dots 142 to the continuous level e_{CB} of a base semiconductor material of the quantum-dot stacked structure QD1. Hence, as described in the item (2), the reason why the absorption in the transition of the carriers from the confined level e_{QD} of the quantum dots 142 to the continuous level e_{CB} of the barrier layer 141 is made to appear out of the area of the atmospheric window is that, in the case where the two responsivity peak wavelengths are set within a range of the single atmospheric window for the detection of an infrared ray and a temperature of an object is calculated with the two-color temperature measurement method to be described later, the absorption in the transition of the carriers from the confined level e_{QD} to the continuous level e_{CB} is an obstacle for detecting the infrared ray with the two responsivity peak wavelengths.

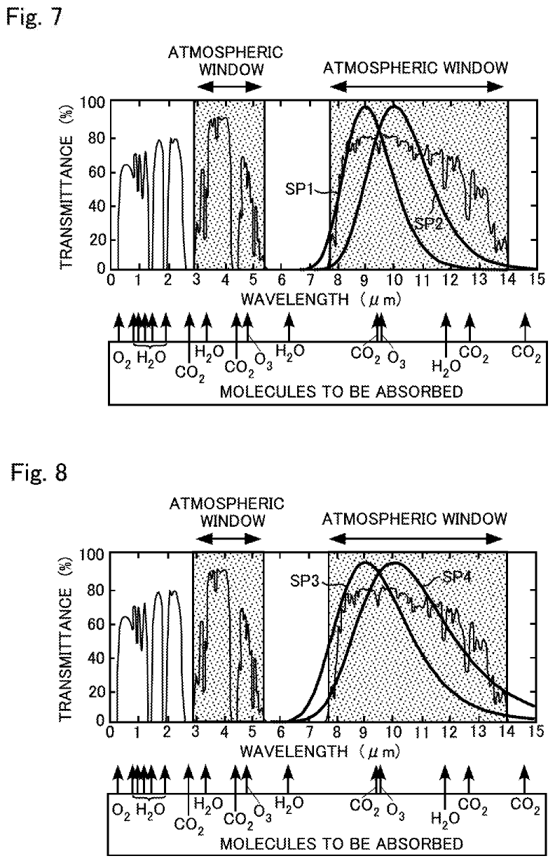

FIG. 7 illustrates a relationship between a transmittance and a wavelength in the first embodiment. In FIG. 7, the vertical axis represents the transmittance and the horizontal axis represents the wavelength. Moreover, a responsivity spectrum SP1 represents a responsivity spectrum appearing when a voltage of −0.5 V is applied to the photoelectric conversion layer 14, and a responsivity spectrum SP2 is a responsivity spectrum appearing when a voltage of 0.5 V is applied to the photoelectric conversion layer 14.

With reference to FIG. 7, as molecules found in the air and to be absorbed, those of water (H₂O), oxygen (O₂), ozone (O₃), and carbon dioxide (CO₂) are illustrated in association with the absorption wavelengths.

When the voltage of −0.5 V is applied to the photoelectric conversion layer 14, the detection unit 1 obtains a photocurrent I1, in accordance with the responsivity spectrum SP1, an emission from the object (including an emissivity), and a transmittance. Moreover, when the voltage of 0.5 V is applied to the photoelectric conversion layer 14, the detection unit 1 obtains a photocurrent I2, in accordance with the responsivity spectrum SP2, an emission from the object (including an emissivity), and a transmittance.

The responsivity spectrum SP1 has a responsivity peak wavelength of 9 μm, and the responsivity spectrum SP2 has a responsivity peak wavelength of 10 μm. The responsivity peak wavelengths of 9 μm and 10 μm appear in the transition of the carriers from the confined level e_{QD} of the quantum dots 142 to the level e_{WELL} of the quantum well layer 143. That, is, the responsivity peak wavelengths of 9 μm and 10 μm appear due to the same transition. Then, the responsivity peak wavelengths of 9 μm and 10 μm appear in a wavelength range of the atmospheric window from 8 μm to 14 μm. That is, the responsivity peak wavelengths of 9 μm and 10 μm appear in a wavelength range of the same atmospheric window. Moreover, the responsivity peak of the responsivity spectrums SP1 and SP2 has a half width of 30 meV.

FIG. 8 illustrates another relationship between the transmittance and the wavelength in the first embodiment. In FIG. 8, the vertical axis represents the transmittance and the horizontal axis represents the wavelength. Moreover, a responsivity spectrum SP3 represents a responsivity spectrum appearing when a voltage of −0.5 V is applied to the photoelectric conversion layer 14, and a responsivity spectrum SP4 is a responsivity spectrum appearing when a voltage of 0.5 V is applied to the photoelectric conversion layer 14. The responsivity spectrums SP3 and SP4 illustrated in FIG. 8 appear when the variation in size of the quantum dots 142 increases or when a level to which the carriers make a transition is controlled.

With reference to FIG. 8, when the voltage of −0.5 V is applied to the photoelectric conversion layer 14, the detection unit 1 obtains a photocurrent I3, in accordance with the responsivity spectrum SP3, an emission from an object (including an emissivity), and a transmittance. Moreover, when the voltage of 0.5 V is applied to the photoelectric conversion layer 14, the detection unit 1 obtains a photocurrent I4, in accordance with the responsivity spectrum SP4, an emission from the object (including an emissivity), and a transmittance.

The responsivity peak of the responsivity spectrums SP3 and SP4 has a half width of 45 meV. The responsivity spectrums SP3 and SP4 respectively have the same responsivity peak wavelengths as the responsivity spectrums SP1 and SP2 have. As a result, the responsivity spectrums SP3 and SP4 have a larger absorption bandwidth than the responsivity spectrums SP1 and SP2 have.

Hence, the increase in size variation of the quantum dots 142 or the control of the level to which the carriers transit makes it possible to enlarge the absorption bandwidth of the infrared ray and increase the signal intensity.

The calculator 5 receives the photocurrents I1 and I2 from the detector 2. Then, the calculator 5 calculates a temperature T of the object based on the I1 and I2, using the two-color temperature measurement method.

The photocurrent I1 to be detected by the detection unit 1 in the application of the voltage V1 is determined by wavelength integration of a responsivity spectrum 1, a transmittance, an illumination spectrum of a black body, and an emissivity of the detection unit 1 in the application of the voltage V1. In a similar manner, the photocurrent I2 to be detected by the detection unit 1 in the application of the voltage V2 is determined by wavelength integration of a responsivity spectrum 2, a transmittance, an illumination spectrum of a black body, and an emissivity of the detection unit 1 in the application of the voltage V2.

Described below is a basis of how to calculate the temperature T of the object, using two kinds of photocurrents. Considered first is two kinds of known responsivity spectrums (different responsivity peak wavelengths) in the detection unit 1. The two kinds of responsivity spectrums in this embodiment of the present invention are obtained from the voltages V1 and V2 to be applied to the detection unit 1. Moreover, an illumination spectrum of a black body depends on a temperature. Hence, a ratio of wavelength integration (a ratio of the photocurrents) Iₒ1/Iₒ2 between each of the two kinds of responsivity spectrums, the illumination spectrum of the black body, and the transmittance is previously determined based on the temperature of the black body since the transmittance is already known. In other words, Iₒ1/Iₒ2 is determined based on a temperature.

Considered next is a ratio I1/I2 of the photocurrents detected by the detection unit 1. In this embodiment of the present invention, it is assumed that the transmittance is already known and the emissivities of the object are equal. Hence, the ratio I1/I2 is determined based on the responsivity spectrums, the transmittance, the illumination spectrum of the black body, and the emissivity. The ratio I1/I2 is the same as the ratio Iₒ1/Iₒ₂ obtained from the responsivity spectrums, the transmittance, and the illumination spectrum of the black body. Hence, the temperature T of the object can be calculated based on the relationship I1/I2=Iₒ1/Iₒ2. Here, a common two-color temperature measurement method involves measuring a temperature with two different responsivity peak wavelengths having an equal emissivity. If the emissivity is completely equal, the temperature T of the object is measured in high accuracy. However, how to define a temperature error is different, depending on the use of the temperature. Hence, the “equal” emissivity is not limited to be completely equal but is within tolerance to some degree. For example, the difference in emissivity may be within 10% (preferably within 1%). In the present application, the above emissivity is interpreted to be “equal” or “constant.” In this embodiment of the present invention, the infrared detection apparatus calculates a temperature of the object in which emissivities in two responsivity peak wavelengths are interpreted to be equal or constant. Note that such objects as paper, wood, concrete, and a face of oxidized metal are examples of the objects whose emissivities are equal or constant in two responsivity peak wavelengths.

Hence, with the above technique, the calculator 5 calculates the temperature T of the object, using two kinds of photocurrents without correcting the emissivity. Moreover, the detection unit 1 uses quantum dots, eliminating the needs of a bandpass filter and contributing to an increase in detection intensity, reduction in cost, and downsizing of the detection unit 1.

When receiving the photocurrents I3 and I4 from the detection unit 1, the calculator 5 calculates the temperature T of the object with the similar technique based on the photocurrents I3 and I4. In calculating the temperature T of the object, the use of the responsivity spectrums SP3 and SP4 in FIG. 8 raises the signal intensity higher than the use of the responsivity spectrums SP1 and SP2 in FIG. 7. Hence, the temperature T of the object can be calculated with the two-color temperature measurement method with a higher signal intensity.

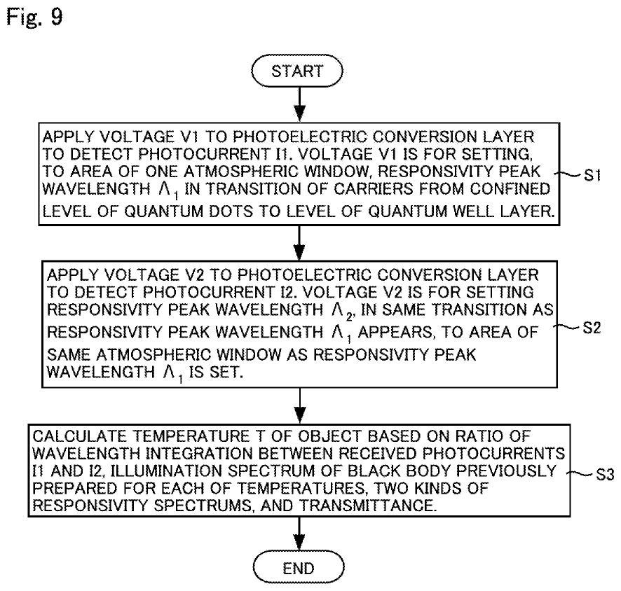

FIG. 9 shows a flowchart to explain how to calculate a temperature of an object according to the first embodiment. With reference to FIG. 9, when an operation to calculate the temperature T of the object starts, the voltage V1 is applied to the photoelectric conversion layer 14 to detect the photocurrent I1 (Step S1). Here, the voltage V1 is for setting, to an area of one atmospheric window, a responsivity peak wavelength λ₁ in the transition of carriers from a confined level of quantum dots to a level of a quantum well layer.

Then, the voltage V2 is applied to the photoelectric conversion layer 14 to detect the photocurrent I2 (Step S2). Here, the voltage V2 is for setting a responsivity peak wavelength λ₂, in the same transition as the responsivity peak wavelength λ₁ appears, to an area of the same atmospheric window as the responsivity peak wavelength λ₁ is set.

Then, the calculator 5 receives the photocurrents I1 and I2 from the detector 2, and calculates the temperature T of the object based on a ratio of wavelength integration between the received photocurrents I1 and I2, an illumination spectrum of the black body previously prepared for each of the temperatures, two kinds of responsivity spectrums, and a transmittance (Step S3). Hence, the operation of calculating the temperature T of the object ends.

Thus, the temperature T of the object is calculated with the two-color temperature measurement method, based on a value detected by sweeping the voltages applied to the photoelectric conversion layer 14 to set the two responsivity peak wavelengths; namely, λ₁ and λ₂.

According to the above first embodiment, the detection unit 1 detects photocurrents each having one of the two responsivity peak wavelengths λ₁ and λ₂ whose emissivities ε (λ₁) and ε (λ₂) are assumed to be equal. Based on the detected two photocurrents, the temperature T of the object is calculated with the two-color temperature measurement method. As a result, the temperature T of the object can be calculated with the emissivities ignored. Such features keep from making a calculation error due to the difference in emissivity between the two wavelengths, contributing to calculating the temperature T with a less margin of error.

Note that, in the above description, the two responsivity peak wavelengths λ₁ and λ₂ are set within an area of the atmospheric window from 8 μm to 14 μm. In this embodiment of the present invention, the range of the atmospheric window is not limited to the above range. Alternatively, the two responsivity peak wavelengths λ₁ and λ₂ may be set within a range of the atmospheric window from 3 μm to 5.5 μm. That is, in this embodiment of the present invention, the two responsivity peak wavelengths λ₁ and λ₂ may be set within either one of the areas of the atmospheric windows; namely, from 3 μm to 5.5 μm or from 8 μm to 14 μm.

### Second Embodiment

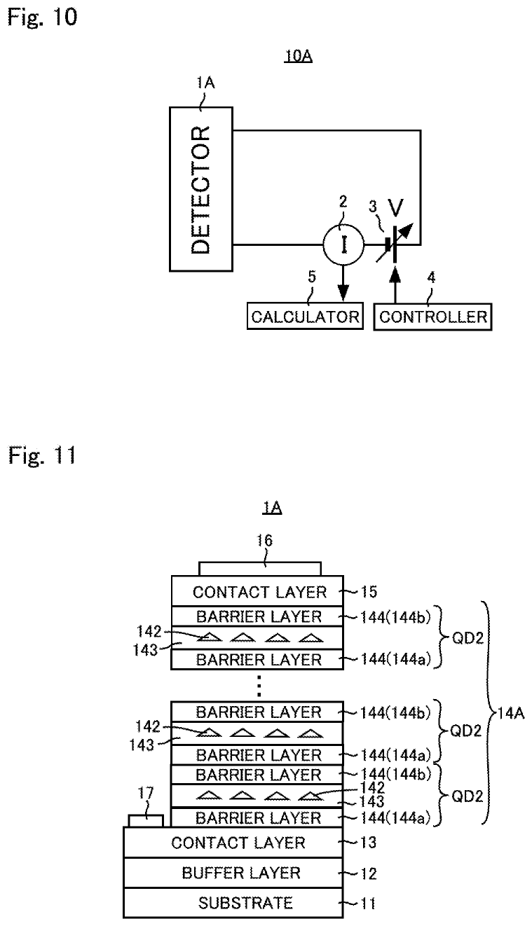

FIG. 10 schematically illustrates an infrared detection apparatus according a second embodiment. With reference to FIG. 10, an infrared detection apparatus 10A in the second embodiment is the infrared detection apparatus 10 illustrated in FIG. 1 with the detection unit 1 replaced by a detection unit 1A. Other features are the same as those in the infrared detection apparatus 10.

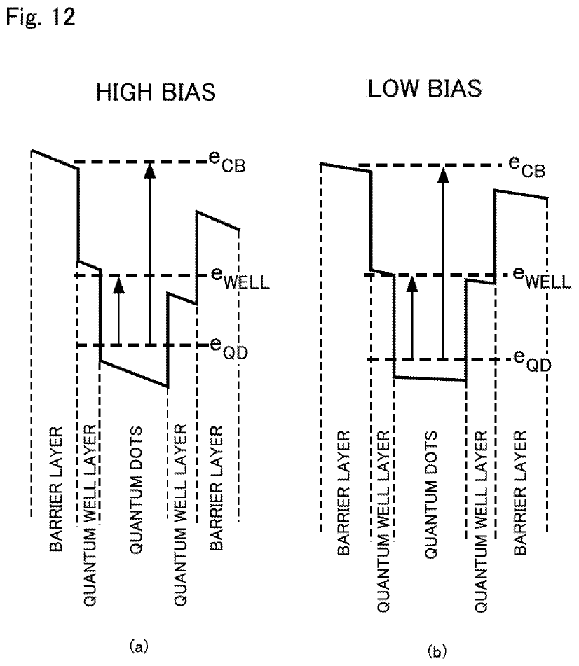

FIG. 11 schematically illustrates the detection unit 1A illustrated in FIG. 10. With reference to FIG. 11, the detection unit 1A is the detection unit 1 illustrated in FIG. 2 with the photoelectric conversion layer 14 replaced by a photoelectric conversion layer 14A. Other features are the same as those in the detection unit 1.

The photoelectric conversion layer 14A is the photoelectric conversion layer 14 illustrated in FIG. 2 with the barrier layer 141 replaced by a barrier layer 144. Other features are the same as those in the photoelectric conversion layer 14.

In the photoelectric conversion layer 14A, the barrier layer 144 includes two barrier layers 144. One of the barrier layers 144; namely, a barrier layer 144a, is placed on one of faces of the quantum well layer 143, and another one of the barrier layers 144; namely, a barrier layer 144b, is placed on another one of the faces of the quantum well layer 143. As a result, the barrier layer 144 (144a), the quantum well layer 143, the quantum dots 142, the quantum well layer 143, and the barrier layer 144 (144b) constitute a quantum-dot stacked structure QD2. Hence, the photoelectric conversion layer 14A includes multiple quantum-dot stacked structures QD2 stacked together.

The barrier layer 144 is made of, for example, AlGaAs. A specific composition of AlGaAs is, for example, Al_{0.2}Ga_{0.8}As. Moreover, the barrier layers 144a and 144b have a combined thickness of, for example, 40 nm. Each of the barrier layers 144a and 144b has a thickness of, for example, 20 nm.

Note that other semiconductors such as InGaP, InAlAs, AlGaAsSb, AlGaInP, and InAlGaAs are appropriately combined to form the quantum-dot stacked structure QD2 and the detection unit 1A. For example, the quantum dots 142 made of InAs may be surrounded by the quantum well layer 143 made of InGaAs, and each of InGaAs, InAs, and InGaAs may be separated by InGaP, thereby forming the photoelectric conversion layer 14A. In this case, a composition of InGaP is, for example, In_{0.48}Ga_{0.52}P.

The detection unit 1A is manufactured in accordance with the steps (a) to (j) in FIGS. 3 to 5. Here, in the steps (d), (g), and (h), the barrier layer 141 is replaced by the barrier layer 144 made of Al_{0.2}Ga_{0.8}As.

FIG. 12 illustrates energy bands in the quantum-dot stacked structure QD2 of the detection unit 1A illustrated in FIG. 11. Note that an illustration (a) in FIG. 12 shows an energy band in the quantum-dot stacked structure QD2 when a high bias voltage is applied, and an illustration (b) in FIG. 12 shows an energy band in the quantum-dot stacked structure QD2 when a low bias voltage is applied.

With reference to FIG. 12, a confined level e_{QD} is found in the quantum dots 142, a level e_{WELL} is found in the quantum well layer 143, and a level e_{CB} is found in the barrier layer 144. Hence, the high bias voltage is applied to the photoelectric conversion layer 14A, so that mainly detected is a photocurrent which derives from absorption of an infrared ray in transition of the carriers from the confined level e_{QD} of the quantum dots 142 to the level e_{WELL} of the quantum well layer 143 (see the illustration (a) in FIG. 12).

Moreover, the low bias voltage is applied to the photoelectric conversion layer 14A, so that mainly detected is a photocurrent which derives from absorption of an infrared ray in transition of the carriers from the confined level e_{QD} of the quantum dots 142 to the level e_{CB} of the barrier layer 144 (see the illustration (b) in FIG. 12).

The above techniques utilize a feature that an absorption coefficient in the transition of the carriers from the confined level e_{QD} of the quantum dots 142 to the level e_{WELL} of the quantum well layer 143 is generally larger than an absorption coefficient in the transition of the carriers from the confined level e_{QD} of the quantum dots 142 to the level e_{CB} of the barrier layer 144.

Hence, the responsivity peak wavelength in the transition of the carriers from the confined level e_{QD} of the quantum dots 142 to the level e_{WELL} of the quantum well layer 143 is set to the wavelength range of an atmospheric window from 8 μm to 14 μm, thereby detecting an infrared ray. The responsivity peak wavelength in the transition of the carriers from the confined level e_{QD} of the quantum dots 142 to the level e_{CB} of the barrier layer 144 is set to the wavelength range of an atmospheric window from 3 μm to 5.5 μm, thereby detecting an infrared ray. This is because the responsivity peak wavelength in the transition of the carriers from the confined level e_{QD} of the quantum dots 142 to the level e_{WELL} of the quantum well layer 143 is set longer than the responsivity peak wavelength in the transition of the carriers from the confined level e_{QD} of the quantum dots 142 to the level e_{CB} of the barrier layer 144 is.

Hence, the detection unit 1A detects an infrared ray: by setting the responsivity peak wavelength λ₁, of the two responsivity peak wavelengths λ₁ and λ₃, to the wavelength range of the atmospheric window ranging from 8 μm to 14 μm; and by setting the responsivity peak wavelength λ₃ to the wavelength range of the atmospheric window ranging from 3 μm to 5.5 μm. That is, in the detection unit 1A, the two responsivity peak wavelengths λ₁ and λ₃ each appear in different transitions, and the detection unit 1A detects the infrared ray by setting the two responsivity peak wavelengths λ₁ and λ₃ to wavelength ranges of different atmospheric windows.

Then, when the voltage V1 is applied to the photoelectric conversion layer 14A, the responsivity of the responsivity peak wavelength λ₁ divided by the responsivity of the responsivity peak wavelength λ₃ ([the responsivity of the responsivity peak wavelength λ₁]/[the responsivity of the responsivity peak wavelength λ₃]) equals to 2 or greater. When the voltage V2 is applied to the photoelectric conversion layer 14A, the responsivity of the responsivity peak wavelength λ₃ divided by the responsivity of the responsivity peak wavelength λ₁ ([the responsivity of the responsivity peak wavelength λ₃]/[the responsivity of the responsivity peak wavelength λ₁]) equals to 2 or greater.

If [the responsivity of the responsivity peak wavelength λ₁]/[the responsivity of the responsivity peak wavelength λ₃] is 2 or greater, and [the responsivity of the responsivity peak wavelength λ₃]/[the responsivity of the responsivity peak wavelength λ₁] is 2 or greater, the responsivity of the responsivity peak wavelengths can be defined, allowing for measurement using the two-color temperature measurement method. Moreover, if [the responsivity of the responsivity peak wavelength λ₁]/[the responsivity of the responsivity peak wavelength λ₃] is 5 or greater and [the responsivity of the responsivity peak wavelength λ₃]/[the responsivity of the responsivity peak wavelength λ₁] is 10 or greater, the detection out of the responsivity peak wavelengths is lower. Such features make it possible to reduce noise and increase measurement accuracy.

Note that, in the second embodiment, a second quantum well layer may be provided to sandwich the first quantum well layer. Here, generated other than the two responsivity peak wavelengths is a responsivity peak wavelength in the transition from the confined level e_{QD} of the quantum dots 142 to a level e_{QW2} of the second quantum well layer. Meanwhile, for example, the second quantum well layer is designed to be formed thin to enhance the quantum confined effect, so that the responsivity peak wavelength in the transition from the confined level e_{QD} of the quantum dots 142 to the level e_{QW2} of the second quantum well layer corresponds to the responsivity peak wavelength in the transition from the confined level e_{QD} of the quantum dots 142 to the continuous level e_{CB} in the conduction band of the barrier layer 141. Such features make it possible to produce only two responsivity peak wavelengths, keeping from affecting the measurement with the two-color temperature measurement method.

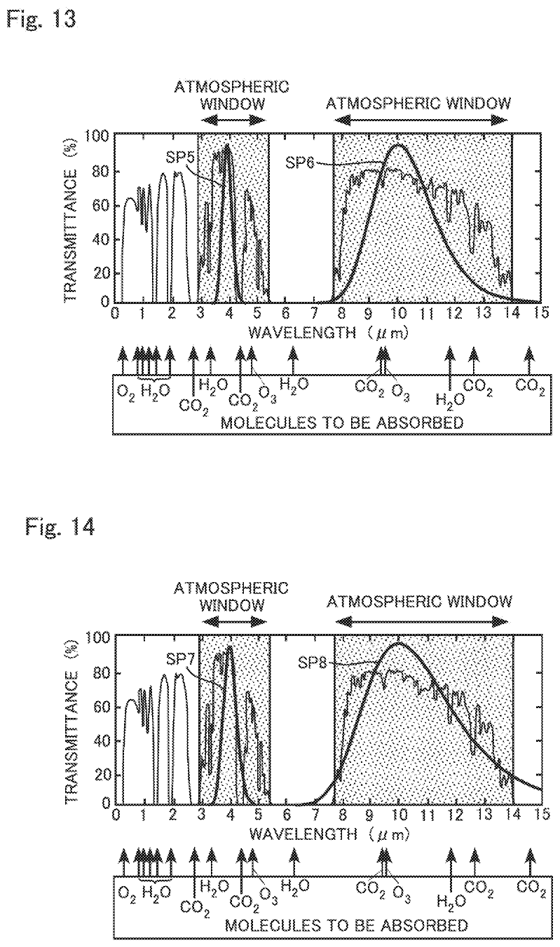

FIG. 13 illustrates a relationship between a transmittance and a wavelength in the second embodiment. In FIG. 13, the vertical axis represents the transmittance and the horizontal axis represents the wavelength. Moreover, a responsivity spectrum SP5 represents a responsivity spectrum appearing when a voltage of 1 V is applied to the photoelectric conversion layer 14A, and a responsivity spectrum SP6 is a responsivity spectrum appearing when a voltage of 5 V is applied to the photoelectric conversion layer 14A.

With reference to FIG. 13, when the voltage of 1 V is applied to the photoelectric conversion layer 14A, the detection unit 1A obtains a photocurrent I5, in accordance with the responsivity spectrum SP5, an emission from an object (including an emissivity), and a transmittance. Moreover, when the voltage of 5 V is applied to the photoelectric conversion layer 14A, the detection unit 1A obtains a photocurrent I6, in accordance with the responsivity spectrum SP6, an emission from the object (including an emissivity), and a transmittance.

The responsivity spectrum SP5 has a responsivity peak wavelength of 4 μm, and the responsivity spectrum SP6 has a responsivity peak wavelength of 10 μm. The responsivity peak wavelength of 4 μm appears in the transition of the carriers from the confined level e_{QD} of the quantum dots 142 to the level e_{CB} of the barrier layer 144. The responsivity peak wavelength of 10 μm appears in the transition of the carriers from the confined level e_{QD} of the quantum dots 142 to the level e_{WELL} of the quantum well layer 143. That is, the responsivity peak wavelengths of 4 μm and 10 μm appear in different transitions. Then, the responsivity peak wavelength of 4 μm appears in a wavelength range of the atmospheric window from 3 μm to 5.5 μm, and the responsivity peak wavelength of 10 μm appears in a wavelength range of the atmospheric window from 8 μm to 14 μm. That is, the responsivity peak wavelengths of 4 μm and 10 μm appear in the wavelength ranges of different atmospheric windows. Moreover, the responsivity peak of the responsivity spectrums SP5 and SP6 has a half width of 30 meV.

A different responsivity peak is obtained, depending on the result in FIG. 13. Hence, the temperature of the object can be calculated with the above two-color temperature measurement method. Moreover, compared with the first embodiment, the two responsivity spectrums SP5 and SP6 do not overlap. Thus, the detections of the infrared ray using the two wavelengths can be separated, and a short wavelength range of 4 μm is used. As a result, a high S/N can be obtained. Hence, the infrared detection apparatus to be provided can calculate a temperature of an object with the two-color temperature measurement method achieving both the high S/N and separation of wavelengths. Moreover, compared with the first embodiment, the difference between the two wavelengths in this embodiment can be set larger. As to the accuracy of calculating the temperature of the object, the tolerance between the differences in the emissivity, of the object, in the wavelengths in this embodiment is larger than that in the first embodiment. Moreover, the infrared detection apparatus 10A of the second embodiment calculates the temperature of the object with the two-color temperature measurement method utilizing different transitions, making it possible to provide an infrared detection apparatus calculating the temperature of the object, with the two-color temperature measurement method using one of the biases alone (for example, a positive bias alone or a negative bias alone). Moreover, both of the two peaks appear in an area of an atmospheric window, allowing for the use of the infrared detection apparatus 10A in a variety of applications such as capturing an object distant apart.

FIG. 14 illustrates another relationship between the transmittance and the wavelength in the second embodiment. In FIG. 14, the vertical axis represents the transmittance and the horizontal axis represents the wavelength. Moreover, a responsivity spectrum SP7 represents a responsivity spectrum appearing when a voltage of 1 V is applied to the photoelectric conversion layer 14A, and a responsivity spectrum SP8 is a responsivity spectrum appearing when a voltage of 5 V is applied to the photoelectric conversion layer 14A. The responsivity spectrums SP7 and SP8 illustrated in FIG. 14 appear when the variation in size of the quantum dots 142 increases or when a level to which the carriers make a transition is controlled.

With reference to FIG. 14, when the voltage of 1 V is applied to the photoelectric conversion layer 14A, the detection unit 1A obtains a photocurrent I7, in accordance with the responsivity spectrum SP7, an emission from an object (including an emissivity), and a transmittance. Moreover, when the voltage of 5 V is applied to the photoelectric conversion layer 14A, the detection unit 1A obtains a photocurrent I8, depending on the responsivity spectrum SP8, an emission from the object (including an emissivity), and a transmittance.

The responsivity peak of the responsivity spectrums SP7 and SP8 has a half width of 45 meV. The responsivity spectrums SP7 and SP8 respectively have the same responsivity peak wavelengths as the responsivity spectrums SP5 and SP6 have. As a result, the responsivity spectrums SP7 and SP8 have a larger absorption bandwidth than the responsivity spectrums SP5 and SP6 have.

Hence, the increase in size variation of the quantum dots 142 or the control of the level to which the carriers transit makes it possible to enlarge the absorption bandwidth of the infrared ray and increase the signal intensity.

Using different transitions, the detection unit 1A can enlarge the absorption bandwidth while separating detections of the infrared ray using two wavelengths. Furthermore, using areas of different atmospheric windows, the detection unit 1A can sufficiently enlarge the absorption range. Such features make it possible to provide the infrared detection apparatus 10A utilizing the two-color temperature measurement method capable of both enhancing the signal intensity in the two-color temperature measurement method (a high S/N and enlargement of an absorption bandwidth) and separating detections of an infrared ray in two wavelengths. Furthermore, the variation in size of the quantum dots 142 may be large, allowing for easily manufacturing the detection unit 1A (QDIP).

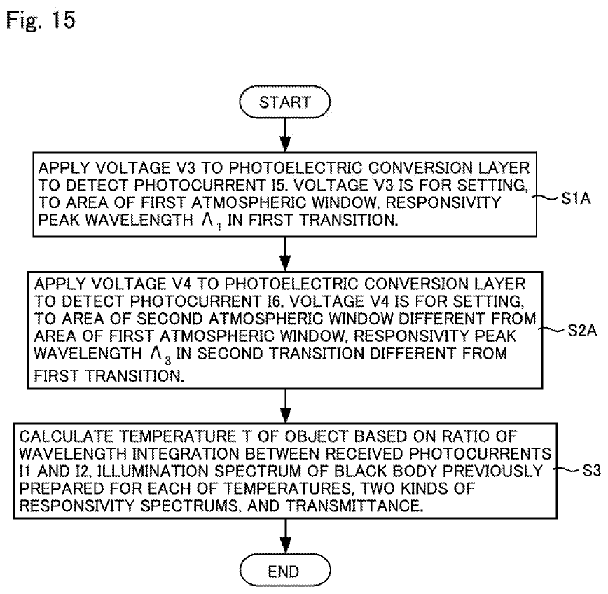

FIG. 15 shows a flowchart to explain how to calculate a temperature of an object according to the second embodiment. The flowchart illustrated in FIG. 15 is the flowchart illustrated in FIG. 9 with Steps S1 and S2 respectively replaced by Steps S1A and S2A. Otherwise, both of the flowcharts are the same.

With reference to FIG. 15, when an operation to calculate the temperature T of the object starts, a voltage V3 is applied to the photoelectric conversion layer 14A to detect a photocurrent 5 (Step S1A). Here, the voltage V3 is for setting, to an area of a first atmospheric window, a responsivity peak wavelength λ₁ in a first transition.

Then, a voltage V4 is applied to the photoelectric conversion layer 14A to detect a photocurrent I6 (Step S2A). Here, the voltage V4 is for setting, to an area of a second atmospheric window different from the area of the first atmospheric window, a responsivity peak wavelength λ₃ in a second transition different from the first transition.

Then, Step S3 described above is executed to calculate the temperature T of the object.

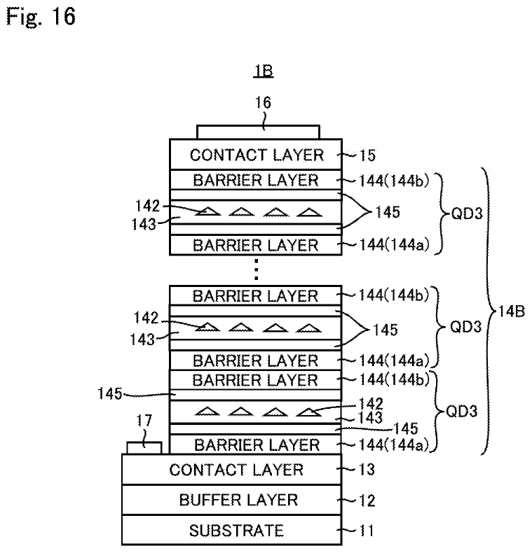

FIG. 16 schematically illustrates another detection unit according the second embodiment. In the second embodiment, the infrared detection apparatus 10A may include a detection unit 1B illustrated in FIG. 16 instead of detection unit 1A.

With reference to FIG. 16, the detection unit 1B is the detection unit 1A illustrated in FIG. 11 with the photoelectric conversion layer 14A replaced by a photoelectric conversion layer 14B. Other features are the same as those in the detection unit 1A.

The photoelectric conversion layer 14B is the photoelectric conversion layer 14A illustrated in FIG. 11 further including a quantum well layer 145. Other features are the same as those in the photoelectric conversion layer 14A.

The quantum well layer 145 is placed between, and in contact with, the quantum well layer 143 and the barrier layer 144. For example, the quantum well layer 145 is made of GaAs and has a thickness of 1 nm or thinner.

Note that the barrier layer 144 (144a), the quantum well layer 145, the quantum well layer 143, the quantum dots 142, the quantum well layer 143, the quantum well layer 145, and the barrier layer 144 (144b) constitute a quantum-dot stacked structure QD3.

When there are two infrared responsivity peaks for an infrared ray, a level of the quantum well layer 145 needs to be close to a level of the barrier layer 144. Hence, the thickness of the quantum well layer 145 is set to 1 nm or thinner.

The quantum well layer 145 provided allows for crystal-growth of the quantum dots 142 and the quantum well layer 143 with high quality.

The detection unit 1B is manufactured in the following steps: in the steps (a) to (j) illustrated in FIGS. 3 to 5, a step for forming the quantum well layer 145 is added between the steps (d) and (e) and between the steps (f) and (g); and, in the step (h), a step for forming the quantum well layer 145 is added between the step for forming the barrier layer 141 and the step for forming the quantum well layer 143.

In using the detection unit 1B, the operation to calculate the temperature of the object is executed according to the flowchart illustrated in FIG. 15.

Other descriptions in the second embodiment are the same as those in the first embodiment.

### Third Embodiment

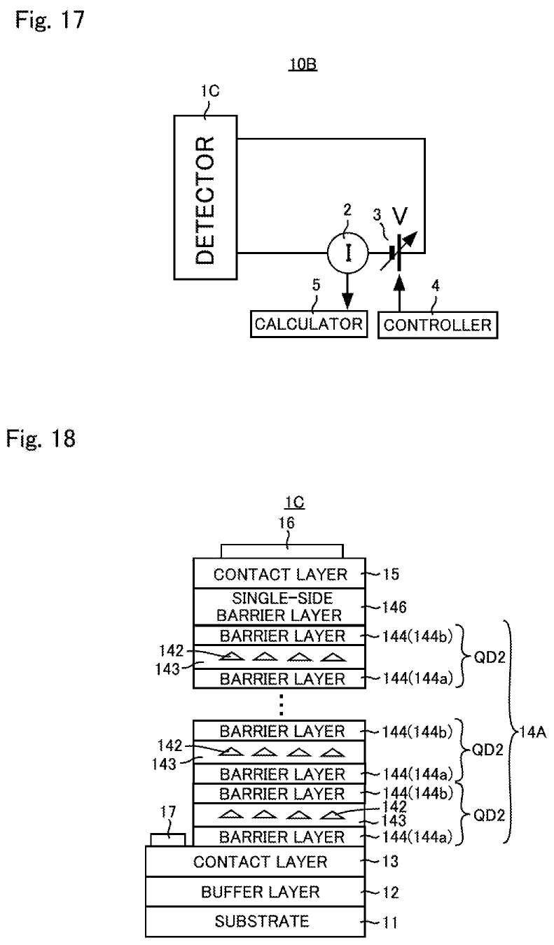

FIG. 17 schematically illustrates an infrared detection apparatus according a third embodiment. With reference to FIG. 17, an infrared detection apparatus 10B in the third embodiment is the infrared detection apparatus 10A illustrated in FIG. 10 with the detection unit 1A replaced by a detection unit 1C. Other features are the same as those in the infrared detection apparatus 10A.

FIG. 18 schematically illustrates the detection unit 1C illustrated in FIG. 17. With reference to FIG. 18, the detection unit 1C is the detection unit 1A illustrated in FIG. 11 additionally including a single-side barrier layer 146. Other features are the same as those in the detection unit 1A.

The single-side barrier layer 146 is placed between, and in contact with, the photoelectric conversion layer 14A and the contact layer 15. The single-side barrier layer 146 is made of, for example, AlGaAs. A specific composition of AlGaAs is, for example, Al_{0.3}Ga_{0.7}As. That is, the single-side barrier layer 146 is made of a semiconductor material larger in band gap than the barrier layer 144. Moreover, the single-side barrier layer 146 has a thickness of, for example, 40 nm.

Note that other semiconductors such as InGaP, InAlAs, AlGaAsSb, AlGaInP, and InAlGaAs are appropriately combined to form the quantum-dot stacked structure QD2 and the detection unit 1C. For example, the quantum dots 142 made of InAs may be surrounded by the quantum well layer 143 made of InGaAs, and each of InGaAs, InAs, and InGaAs may be separated by InGaP, thereby forming the photoelectric conversion layer 14C. In this case, a composition of InGaP is, for example, In_{0.48}Ga_{0.52}P.

The detection unit 1C is manufactured in the steps (a) to (j) in FIG. 3 to 5, with a step for forming the single-side barrier layer 146 additionally included between the steps (h) and (i).

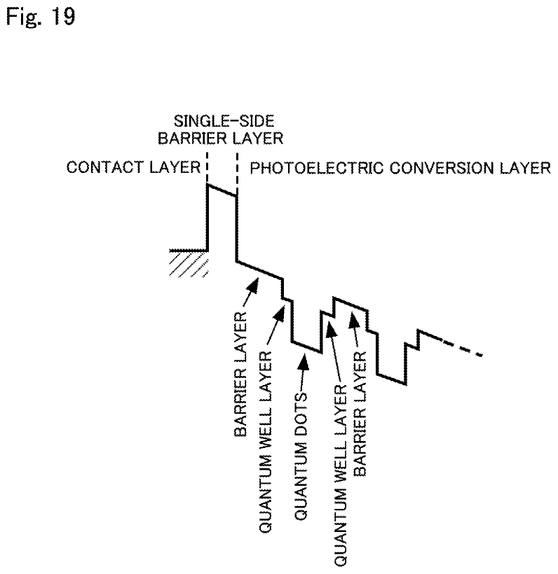

FIG. 19 illustrates an energy band in the photoelectric conversion layer 14A, the single-side barrier layer 146, and the contact layer 15. Note that FIG. 19 illustrates an energy band in the photoelectric conversion layer 14A with a single-side bias applied, the single-side barrier layer 146, and the contact layer 15.

With reference to FIG. 19, a lower end of a conduction band in the single-side barrier layer 146 is positioned closer to high energy than those in the photoelectric conversion layer 14A and the barrier layer 144 arc. As a result, a dark current from the contact layer 15 can be reduced. The reduction in dark current can improve S/N and achieve high responsivity.

Moreover, when the temperature rises, an increase in thermally excited carriers increases a dark current. However, in the detection unit 1C, the single-side barrier layer 146 can reduce the dark current, making it possible to increase the difference between a photocurrent and the dark current at a high temperature and allowing the detection unit 1C to operate at a high temperature.

In the detection unit 1C, the single-side barrier layer 146 may be placed between the contact layer 13 and the photoelectric conversion layer 14A. Typically, the single-side barrier layer 146 may be placed either between the photoelectric conversion layer 14A and the contact layer 15 or between the contact layer 13 and the photoelectric conversion layer 14A.

Not that, in the infrared detection apparatus 10B, the detection unit 1C may be replaced by the detection unit 1B illustrated in FIG. 16 with the single-side barrier layer 146 additionally included. Here, the single-side barrier layer 146 is placed either between the photoelectric conversion layer 14B and the contact layer 15 or between the contact layer 13 and the photoelectric conversion layer 14B.

In the third embodiment, the operation to calculate the temperature of the object is executed according to the flowchart illustrated in FIG. 15.

The infrared detection apparatus 10B of the third embodiment can achieve the same advantageous effects as those in the second embodiment, and further include a QDIP using a two-color temperature measurement method capable of providing high responsivity and operating at high temperature.

Note that the detection unit 1C in the third embodiment demonstrates the advantageous effects only when a single bias (only when a positive bias or a negative bias) is applied so that the advantageous effects of the single-side barrier layer 146 are achieved.

Other descriptions in the third embodiment are the same as those in the first and second embodiments.

According to the above first to third embodiments, the infrared detection apparatus according to an aspect of the present invention may include:

a detection unit including a photoelectric conversion layer formed in a quantum-dot stacked structure including: quantum dots; a first quantum well layer surrounding the quantum dots; a first barrier layer sandwiching the quantum dots and the first quantum well layer;

an operation device which applies a first voltage and a second voltage to the photoelectric conversion layer, the first voltage and the second voltage being respectively provided for setting a first responsivity peak wavelength and a second responsivity peak wavelength to be used for detecting an infrared ray with the photoelectric conversion layer, and the second responsivity peak wavelength being different from the first responsivity peak wavelength;

a detector which detects (i) a first photocurrent to be output from the detection unit when the first voltage is applied to the photoelectric conversion layer, and (ii) a second photocurrent to be output from the detection unit when the second voltage is applied to the photoelectric conversion layer; and

a calculator which calculates a temperature of an object based on the first photocurrent and the second photocurrent detected by the detector.

The embodiments disclosed herewith are examples in all respects, and shall not be interpreted to be limitative. The scope of the present invention is intended to be disclosed not in the above embodiments, but in the claims. All the modifications equivalent to the features of, and within the scope of, the claims are to be included in the scope of the present invention.

The present invention is applicable to an infrared detection apparatus, an infrared detection method, a program which causes a computer to execute the infrared detection method, and a computer-readable storage medium storing such a program.

What is claimed is:

1. An infrared detection apparatus comprising:
a detection unit including a photoelectric conversion layer constituted by a quantum-dot stacked structure including: quantum dots; a first quantum well layer surrounding the quantum dots; a first barrier layer sandwiching the quantum dots and the first quantum well layer;
an operation device configured to apply a first voltage and a second voltage to the photoelectric conversion layer, the first voltage and the second voltage being respectively provided for setting a first responsivity peak wavelength and a second responsivity peak wavelength to be used for detecting an infrared ray with the photoelectric conversion layer, and the second responsivity peak wavelength being different from the first responsivity peak wavelength;
a detector configured to detect (i) a first photocurrent to be output from the detection unit when the first voltage is applied to the photoelectric conversion layer, and (ii) a second photocurrent to be output from the detection unit when the second voltage is applied to the photoelectric conversion layer; and
a calculator configured to calculate a temperature of an object based on the first photocurrent and the second photocurrent detected by the detector.

2. The infrared detection apparatus according to claim 1, wherein
the photoelectric conversion layer includes a plurality of the quantum-dot stacked structures stacked together.

3. The infrared detection apparatus according to claim 1, wherein
the calculator calculates a temperature of the object based on the first photocurrent and the second photocurrent, using a two-color temperature measurement method.

4. The infrared detection apparatus according to claim 1, wherein
the quantum dots are made of InAs,
the first quantum well layer is made of InGaAs, and
the first barrier layer is made of AlGaAs.

5. The infrared detection apparatus according to claim 1, wherein
the detection unit further includes:
a contact layer; and
a second barrier layer placed between the photoelectric conversion layer and the contact layer, the second barrier layer being larger in band gap than the first barrier layer.

6. The infrared detection apparatus according to claim 5, wherein
the quantum dots are made of InAs,
the first quantum well layer is made of InGaAs,
the first barrier layer is made of AlGaAs having a first band gap, and
the second barrier layer is made of AlGaAs having a second band gap larger than the first band gap.

7. The infrared detection apparatus according to claim 1, wherein
the photoelectric conversion layer further includes a second quantum well layer between the first quantum well layer and the first barrier layer.

8. The infrared detection apparatus according to claim 7, wherein
the quantum dots are made of InAs,
the first quantum well layer is made of InGaAs,
the second quantum well layer is made of GaAs, and
the first barrier layer is made of AlGaAs.

9. The infrared detection apparatus according to claim 2, wherein
the quantum dots are made of InAs,
the first quantum well layer is made of InGaAs, and
the first barrier layer is made of AlGaAs.

10. The infrared detection apparatus according to claim 2, wherein
the detection unit further includes:
a contact layer; and
a second barrier layer placed between the photoelectric conversion layer and the contact layer, the second barrier layer being larger in band gap than the first barrier layer.

11. The infrared detection apparatus according to claim 2, wherein
the photoelectric conversion layer further includes a second quantum well layer between the first quantum well layer and the first barrier layer.

12. The infrared detection apparatus according to claim 9, wherein
the detection unit further includes:
a contact layer; and
a second barrier layer placed between the photoelectric conversion layer and the contact layer, the second barrier layer being larger in band gap than the first barrier layer,
the photoelectric conversion layer further includes a second quantum well layer between the first quantum well layer and the first barrier layer,
the quantum dots are made of InAs,
the first quantum well layer is made of InGaAs,
the second quantum well layer is made of GaAs,
the first barrier layer is made of AlGaAs having a first band gap, and
the second barrier layer is made of AlGaAs having a second band gap larger than the first band gap.

13. The infrared detection apparatus according to claim 1, wherein
the detection unit detects the infrared ray emitted from the object of which an emissivity in the first responsivity peak wavelength and an emissivity in the second responsivity peak wavelength are equal.

14. The infrared detection apparatus according to claim 1, wherein
the first responsivity peak wavelength and the second responsivity peak wavelength appear due to the same transition of carriers in the photoelectric conversion layer.

15. The infrared detection apparatus according to claim 1, wherein
the first responsivity peak wavelength and the second responsivity peak wavelength are set in a wavelength range of the same atmospheric window.

16. The infrared detection apparatus according to claim 15, wherein
a responsivity peak wavelength other than the first responsivity peak wavelength and the second responsivity peak wavelength is set in a wavelength range other than the wavelength range of the same atmospheric window.

17. The infrared detection apparatus according to claim 1, wherein
the first responsivity peak wavelength appears in a first transition of carriers in the photoelectric conversion layer, and
the second responsivity peak wavelength appears in a second transition of the carriers in the photoelectric conversion layer, the second transition being different from the first transition.

18. The infrared detection apparatus according to claim 17, wherein
when the first voltage is applied to the photoelectric conversion layer, a first responsivity divided by a second responsivity equals 2 or greater, the first responsivity being a responsivity of the first responsivity peak wavelength and the second responsivity being a responsivity of the second responsivity peak wavelength, and
when second voltage is applied to the photoelectric conversion layer, a third responsivity divided by a fourth responsivity equals 2 or greater, the third responsivity being a responsivity of the second responsivity peak wavelength and the fourth responsivity being a responsivity of the first responsivity peak wavelength.

19. The infrared detection apparatus according to claim 17, wherein
the first responsivity peak wavelength is set within an area of a first atmospheric window having a first wavelength range, and
the second responsivity peak wavelength is set within in an area of a second atmospheric window having a second wavelength range longer than the first wavelength range.

20. The infrared detection apparatus according to claim 17, wherein
the first voltage and the second voltage is either positive or negative.
